(19) United States
(12) Patent Application Publication
(10) Pub. No.: US 2007/0247196 A1
(43) Pub. Date: Oct. 25, 2007

(54) Circuit and method for configuring a circuit

(76) Inventors: Thomas Niedermeier, Rosenheim (DE); Tim Schonauer, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/400,349

(22) Filed: Apr. 7, 2006

(51) Int. Cl. H03K 19/096

(52) U.S. Cl. 326/95

(57) ABSTRACT

A circuit and method for configuring a circuit is disclosed. In one embodiment, the circuit includes at least one pull-down path, wherein an amount of a current flowing through the pull-down path is determined by a switchable resistivity value of a switchable resistor that is included by the circuit. The invention further provides method for configuring a circuit and to a logic circuit.

### FIELD OF INVENTION

The present invention relates to circuits, especially dynamic logic circuits like dynamic PLAs, and a method for configuring a logic circuit.

### BACKGROUND

Configurable logic devotes a wide field of methods for the adaptation of given chip structures to required logic functions at selected stages in the integrated circuit's life cycle. In particular, methods allowing the exploitation of a post-fabrication logic configurability have the potential for a wide range of benefits, such as an in the field adaptation to changing standards as well as application and user requirements, a design error correction, one hardware for many purposes and applications (flexible interfaces, PAL, programmable logic arrays (PLA), field programmable gate arrays (FPGA)), or high speed yet power efficient data processing through problem and data adaptable execution units. While these benefits are principally acknowledged, configurable logic so far is commercially successful only in few chip concepts; among these are of course the field-programmable gate arrays and perhaps in the midterm also the structured ASICs.

Among the configurable hardware's major problems is in particular the overhead concerning area, power, and cost which is typically needed to realize configurability. Also there are operational issues such as a reload of after power down and a stability of the configuration information.

The configurable logic approach with broadest use today is the field programmable gate array (FPGA) which especially in the area of digital signal processing is able to outperform digital signal processors (DSPs). Although being highly successful as standalone products, FPGAs could not find their way into higher integrated system chips for a long time. It was only the second quarter of 2005 when a first product with embedded FPGA core appeared on the market (STM's GreenFIELD multi-purpose microcontroller for use in wireless infrastructure).

While FPGAs offer high flexibility, todays implementations are accompanied by severe drawbacks making them problematic for high-volume products. The normally SRAM based FPGA designs have a significant area (10+) and power overhead (50+) compared to dedicated logic. Also they need additional non-volatile memory (NVM) to keep the configuration information during power down phases as well as a configuration reload phase after power up.

Another problem is that FPGAs are not (area) efficient at structures with low logic complexity but high fan-ins (many inputs) as needed e.g., to implement finite state machines (FSM). In these cases, Programmable Logic Array (PLA) architectures perform much better. That is why PLA-enhanced hybrid FPGAs were candidates for products for the standalone market.

PLA is the name of a two-stage logic circuit consisting of an “AND-plane” followed by an “OR-plane” to compute any sum of product function. This can be implemented by a consecutive arrangement of wide fan-in NOR structures where the outputs of the first (AND) stage form the inputs of the second (OR) stage. In CMOS circuitry, such wide fan in NOR structures are optimally realized with dynamic instead of static logic due to speed and power reasons. A PLA is typically defined by its number of inputs, the number of product terms (after AND plane) and the number of outputs (after OR plane). PLAs can be designed directly as custom structure or as generic and programmable structure.

In the form of dynamic implementations, PLAs (dPLA) have also raised new interest in high performance designs. For example, a very high-speed implementation (1 GHz) of a PowerPC CPU was built based in a large number of dPLAs for control logic parts. These dPLAs were specifically designed for every individual control task, meaning they are fixed structures and cannot be reprogrammed. At dynamic logic circuits, the output depends on the evaluation of the charge stored in high impedance circuit nodes at a certain point of time. The basic dynamic element often consists of a pre-charge PMOS transistor, an NMOS pull-down network NMOS transistors in parallel arrangement and controlled by inputs, and an NMOS footer transistor. Pre-charge and footer transistor are typically connected to the same clock Φ.

(Re)configurable PLAs had their focus on stand alone devices so far. At this PLA variant the number of inputs, outputs, and product terms is predefined but typically all possible connections between inputs and internal product terms, as well as product terms and outputs are provided (fully populated matrix). To program/configure such a PLA it must be possible to remove not needed connections or to switch on or off the pull-down transistors or networks. This is today achieved by using fuses, EEPROM (Electrically Eraseable Programmable Read-Only-Memory) transistors or switch transistors driven by some configuration memory. Fuses show the setback that they are only one time programmable and typically need external programming. EEPROMs disadvantageously need an external programming and use high voltage paths. Switch-transistors with configuration memory need a transistor plus an additional storage element, have a disadvantageous area and locality of the configuration memory and a likely to show higher volatility of its storage.

There are also other solutions to allow a post fabrication implementation of more or less complex logic structures. However, these are either limited in size (spare gates), and/or only one time configurable (e-beam configurable array structures).

In summary it can be stated that until today only partly satisfying solutions exist for the integration of post production (re)configurable logic on today's systems chips, a situation likely to have prevented a wider commercial application of such configurability.

For these and other reasons, there is a need for the present invention.

### SUMMARY

The present invention provides to a circuit having at least one pull-down path, wherein an amount of a current flowing through the pull-down path is determined by a switchable resistivity value of a switchable resistor that is comprised by the circuit. The invention further relates to a method for configuring a circuit and to a logic circuit.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a circuit diagram of prior art alternatives for a configuration of a pull-down path of a dynamic PLA.

FIG. 2 illustrates a circuit diagram of a dynamic logic principle according to prior art.

FIG. 3 illustrates a circuit diagram of a resistor element according to one embodiment of the invention.

FIG. 4 illustrates idealized switching currents for phase change elements.

FIG. 5 illustrates a circuit diagram of one embodiment of a dynamic element with a first resistor-configurable pull-down path.

FIG. 6 illustrates a circuit diagram of another embodiment of a dynamic element with a second resistor-configurable pull-down path.

FIG. 7 illustrates a circuit diagram of a dynamic logic with resistor-configurable pull-down paths.

FIG. 8 illustrates a circuit diagram of a configurable dynamic NOR logic with separate footer transistors for normal and inverted signal groups.

FIG. 9 illustrates a circuit diagram of another configurable dynamic NOR logic with separate footer transistors for normal and inverted signal groups.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a circuitry and method achieves a reduction of overhead concerning area, power, and/or cost, and allows a highly area efficient post production implementation of a configurable and even reprogrammable logic.

In one embodiment of the invention includes combining dynamic logic concepts, in particular dynamic PLAs, with a new resistor based configuration concept which, in a preferred form, uses a phase change memory (PCM) to determine its resistivity (‘phase change resistor’). Thus, the logic circuit in a gerneral form includes at least one switchable resistor that is adapted to program a logic configuration of the logic circuit.

The phase change or phase change memory (PCM) technology allows to program resistive non-volatile elements. The underlying principle of PCM elements is a thermally induced reversible phase change between an amorphous and a (poly)crystalline phase, often of a chalcogenide glass element but also other suitable compounds.

An amorphous state yields a high resistance, while a polycrystalline state yields a low resistance. The phase change is induced by heat due to a current through the resistive element. The duration and magnitude of the current determines if the element will subsequently have a high or low resistivity. An advantage of PCM is that scaling is actually not harmful but even beneficial: the smaller the structures become, the smaller the currents need to be to induce the phase change. Furthermore phase change elements can be realized with sub lithographical techniques in the upper layers of a CMOS process and therefore can be stacked over the transistors e.g., over the ones which are required to implement the other circuitry.

Thus one can build post-production configurable logic elements building on dynamic logic circuits comprising effective resistor-based switches. Wherein these resistors can be run-time configurable, non-volatite during power down, and minimal in footprint, especially through the preferred use of the Phase-Change Memory (PCM) technology. This may be achieved by, e.g., using a pre-charge transistor and pull down (NOR/OR/AND) elements (i.e., single elements like pull-down transistors or pull-down network(s)) where one feature is that the logical connection and disconnection, resp., is dependent on the selected resistivity value of the switchable resistor. The switchable resistor may be part of this pull-down path and e.g., arranged in series with the other elements of the pull-down path.

Another embodiment of the invention uses a circuit having at least one pull-down path, wherein an amount of a current flowing through the pull-down path is determined by a switchable resistivity value of a switchable resistor that is comprised by the circuit. Under operating conditions this amount of a current typically stems from a pre-charge flowing through the pull-down path. The circuit may further include at least one pre-charge path. The pull-down path may include at least one pull-down element that is arranged in series with the switchable resistor.

Thus, the resistivity can be switched in a controlled way, e.g., to effectively disconnect (i.e., switching to an effectively non-conductive state/state of high resistivity) or connect (i.e., switching to an effectively conductive state/state of low resistivity) a pull-down path. The switchable resistor can, e.g., be regarded as part of the pre-charge path, part of the pull-down path or as interconnection between the pre-charge path and the pull-down path.

Another embodiment of the invention includes a method for configuring a circuit having at least one one switchable resistor with a switchable resistivity, the method including: sending a first current through the resistor to set the resistor to a first resistivity value and sending a second current different from the first current through the resistor to set the resistor to a second resistivity value.

The invention, inter alia, shows the advantages that it can control the resistivity of the resistor(s) by mainly using already available circuit elements and exhibits a controllable resistivity technology with 3D stacking qualities and extremely low footprint. Further advantages are:

reprogrammability (re-configurability);

minimal cost overhead in case the resistor technology is part of production process anyway;

very low area overhead regarding structures specifically needed for implementing or altering the configuration;

extremely low footprint through 3D arrangement since resistors can be placed on top of active logic elements;

robustness against environmental attacks, such as a particles; and

the invention can be used in a wide range of configurable logic structures, preferably in configurable dynamic and/or logic arrangements, such as configurable dynamic PLAs or configurable dynamic decoders.

In FIG. 1, a typical programmable PLA is illustrated where it is possible to permanently switch on or off (connect/disconnect) a pull-down transistor TPD. This is achieved by alternatively using a configuration element, of which alternatively are shown: a fuse F, an EEPROM (Electrically Eraseable Programmable Read-Only-Memory) transistor E, and a switch transistor S driven by some configuration memory. These alternative configuration elements F, E, S are connected between a pre-charge PMOS transistor P on one side, and the pull-down transistor TPD on the other side which in turn is also connected to an NMOS footer transistor N as shown. The pre-charge transistor P and the footer transistor N are connected to the same clock Φ.

Use of the fuse F has the setback that it is only one time switchable/programmable and typically needs external programming. EEPROMs E disadvantageously need an external programming and use high voltage paths. The switch-transistor S with configuration memory needs a transistor plus an additional storage element, has a disadvantageous area and locality of the configuration memory and is likely to show a higher volatility of its storage.

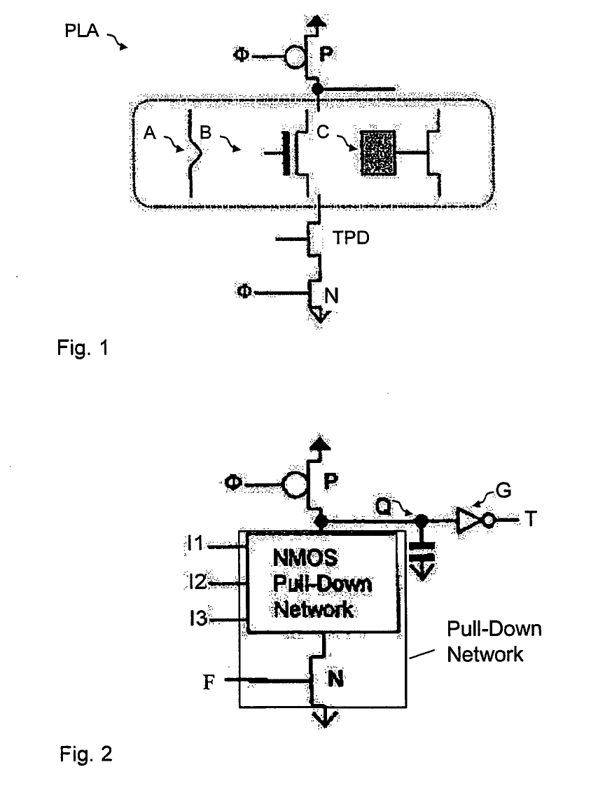

FIG. 2 illustrates a schematic of a dynamic logic circuit where an output depends on the evaluation of a charge stored in high impedance circuit nodes at a certain point of time. The basic dynamic element consists of a pre-charge PMOS transistor P, and a pull-down network comprising a NMOS pull-down network (e.g., NMOS transistors in parallel arrangement and controlled by inputs I1, I2, I3) and a NMOS footer transistor N. The pre-charge transistor P and the footer transistor N are connected to the same clock Φ.

The normal (logic) operation, i.e., the state in which the logic circuit or part of it is operated as logic circuit, generally includes the following phases:

pre-charge phase: during Φ=0 (clock low), transistor P is open and transistor N is closed which allows a charging of an internal node (capacitance) Q; and

evaluation phase: when Φ=1, transistor P closes while transistor N opens and depending on the signal values of the inputs I1, . . . , I3 node Q gets discharged or not. A gate G (inverter) is typically connected to node Q in order to produce a defined signal value T (=−Q).

The circuit of FIG. 2 realizes a NOR (NOT OR) function in that node Q, e.g., it remains on a logical ‘high’ only when I1, I2, and I3 are all in a logical ‘low’ state.

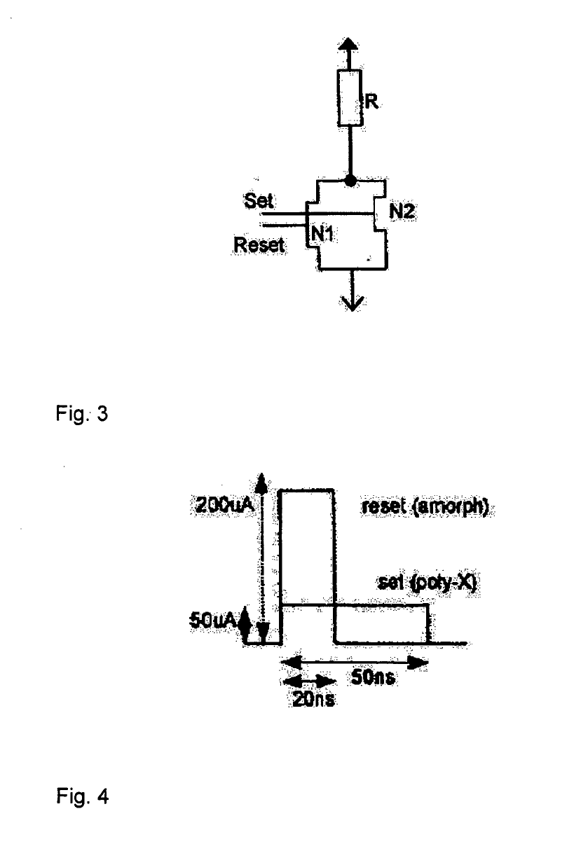

In one embodiment as illustrated in FIG. 3, a switchable resistor R containing an active phase change material is controlled/can be configured via a resistivity switching element connected in series with the resisitor R wherein the resistor R constitutes of two transistors N1 and N2 connected in parallel and being of different dimensions and driving currents Iₒₙ. By activating it for a defined period of time (see FIG. 4), the larger transistor N1 conducts a current high enough to reset the resistor R (compare FIG. 4). The resistor R enters its high resistivity state with the de facto consequence of a deactivation of an associated pull-down path (see below). If N2 gets activated for a defined period of time (see FIG. 4), a smaller current than before will flow which however will heat R enough to bring it into its low resistive state. A low resistor value has then the consequence that the associated pull-down path is activated again.

FIG. 4 illustrates typical values for phase change elements of a reset current (from on to off) of 200 μA over a duration of 20 ns and a subsequent resistivity value R_{off} in the range of 1 MΩ, and a set current (from off to on) of about 50 μA over a duration of 50 ns resulting in a subsequent resistivity value Rₒₙ in the range of 10 kΩ.

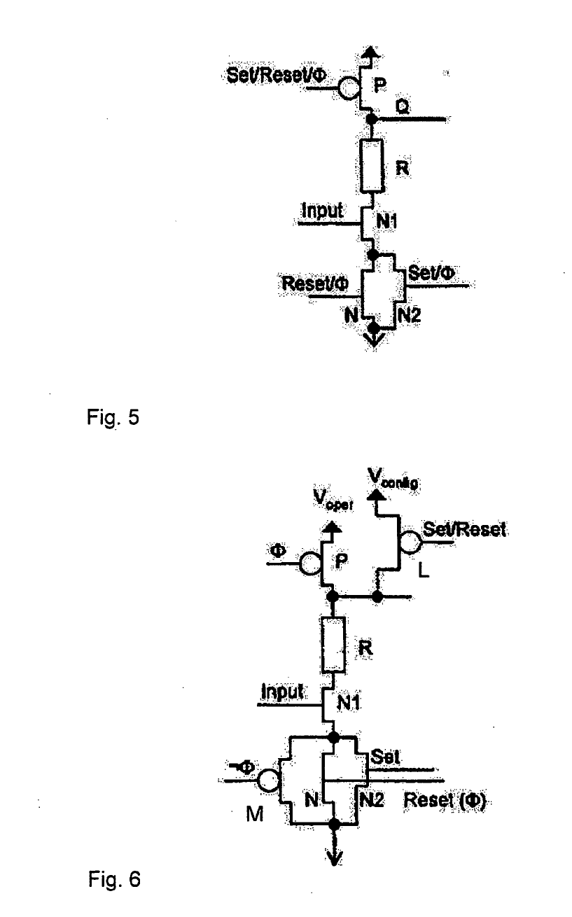

In FIG. 5, above described configuration element is merged with the configurable pull-down path of FIG. 1. This merger replaces the configurable alternatives illustrated in the dashed area of FIG. 1 with resistor R. Transistor N1 may take over the role of the pull-down transistor, while N2 will be placed in parallel to the footer transistor N.

For configuration/resistivity switching, resistor R can be reset via activating transistors P & N1 & N(& N2) and set via transistors P & N1 & N2.

During normal operation (i.e., in a non-configuring state) of the logic circuit, the clock Φ prevents that P & N are open at the same time. Thus the maximum current flowing through the switchable resistor R is limited to the amount of charge stored in node Q after the pre-charge phase. This charge is in modern CMOS logic processes too small that the resulting current will change the state of R.

In this embodiment, the resistivity switching element is part of the pull-down network or vice versa in that the transistors N, N1 act as configuration/control transistors for the resistor R (if the circuitry is in the configuring state) and as transistors of the pull-down path supporting a logic function (if in the normal operation state).

In case problematic conditions should arise either through a very high number inputs (leading to a high capacity Q) or a further shrink of the PCM cell, it could be required to limit the maximum current through resistor R to avoid an unintended reset. This could be achieved either via limiting the charge stored in node Q or by extending the discharge time.

FIG. 6 illustrates an embodiment of one solution that overcomes this problem by use of a p-type instead of a n-type transistor as the footer transistor (needs an inverted clock Φ). This reduces voltage swing and increases resistivity in discharge path and/or use of at least two possibly differently sized pre-charge transistors in combination with two respective supply voltages. Compared to the configuration phase a lower voltage with a perhaps smaller pre-charge transistor is used during operation phase.

In this embodiment, the pre-charge path and the pull-down path contain resistivity switching elements N, N2 (i.e., set/reset transistors) that are not used for logic functions but are separated from the logic elements L, M.

In different embodiments, part or all of the resistivity switching elements could be integrated with logic elements; or only be present in the pre-charge path.

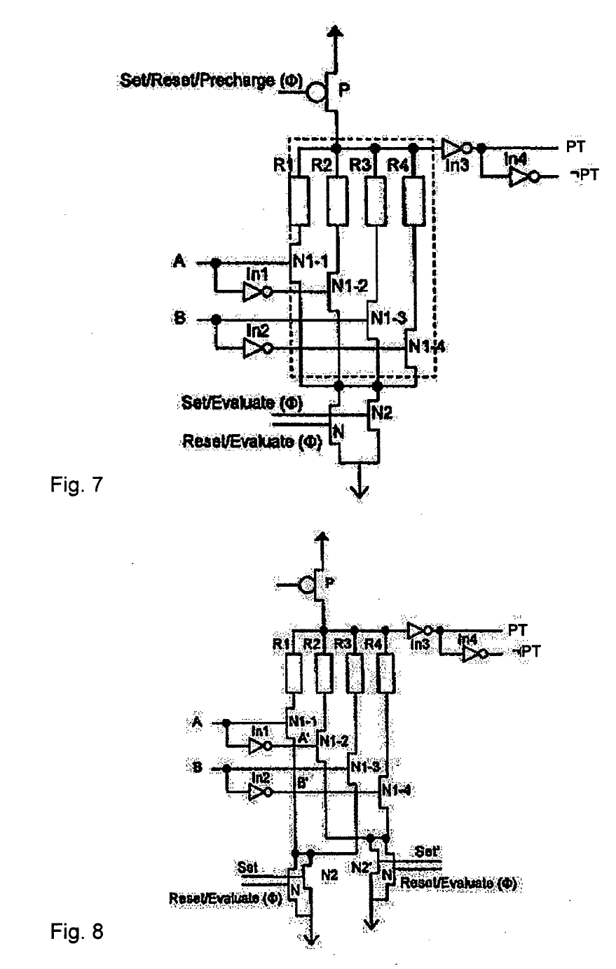

With an additional pull-down paths added, a dynamic OR/NOR logic element will result. FIG. 7 illustrates a fully configurable logic element with two pull-down paths per input signal A, B, one for the non-inverted and one for the inverted value (via inverters In1, In2). Each pull-down path has a respective input transistor N1-1, N1-2, N1-3, N1-4, while all paths share a common (integrated) set of configuration/resistivity switching (control) and evaluation (logic) transistors N, N2. Additionally illustrated are product term _{┐} outputs P, [symbol] P via two inverters In3, In4.

Configuration of such a logic element is done by firstly resetting all resistors R1-R4 in sequence (controlled e.g., via sequential activation of the proper inputs A/B/ . . . e.g., through a one-hot-decoder) and secondly by selectively setting those resistors whose pull-down paths are required for the logic function to be implemented.

Due to the fact that a signal value and its inverse value are present in one block at the same time, proper resetting and setting need additional structures. In another embodiments (see FIG. 8), separate resistivity switching transistors N2, N2′ and footer transistors N, N′ for the pull-down paths with non-inverted inputs (A, B) and for the pulldown paths with inverted inputs (A′, B′) are applied.

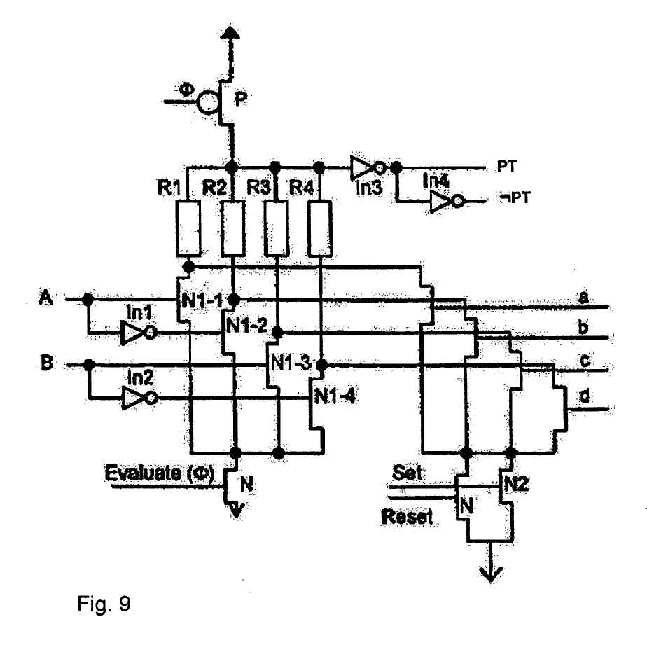

Another embodiment introduces separate transistors and paths for configuration and for normal operation (see FIG. 9). This covers variants where the select transistors N, N2 with inputs a, . . . , d are separate from the pull-down transistors N1-1, . . . , N1-4 and that there are also the separate footer transistor N for discharging and configuration.

A dynamic PLA can then be constructed by:

adding further inputs as required;

replicating this structure depending on the number of required product terms; and

adding second stage elements where the number of inputs corresponds to the number of generated product terms whose total count corresponds to the number of required outputs.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A circuit comprising:
at least one pull-down path, wherein an amount of a current flowing through the pull-down path is determined by a switchable resistivity value of a switchable resistor that is comprised by the circuit.

2. The circuit according to claim 1, comprising wherein, by the switching, the resistivity value is switchable between an effectively conductive state and an effectively non-conductive state.

3. The circuit according to claim 1, comprising wherein the resistivity value is switchable by sending a respective current through the resistor.

4. The circuit according to claim 3, comprising wherein the resistivity value is switchable by sending a respective current through the resistor such that the resistor is set to a first resistivity by sending a first current pulse through it; and
the resistor is set to a second resistivity by sending a second current pulls through the resistor that is different from the first current.

5. The circuit according to claim 4, comprising wherein the resistor is a phase change resistor.

6. The circuit according to claim 1, further comprising at least one pre-charge path, and wherein the pull-down path comprises at least one pull-down element that is arranged in series with the switchable resistor.

7. The circuit according to claim 1, comprising wherein the circuit comprises at least one resistivity switching element that is adapted to switch the at least one switchable resistor.

8. The circuit according to claim 7, comprising wherein the at least one resistivity switching element comprises two transistors that are arranged in parallel.

9. The circuit according to claim 8, comprising wherein the transistors are differently sized.

10. The circuit according to claim 1, comprising wherein the at least one resistivity switching element is functionally a part of the least one pull-down path.

11. The circuit according to claim 7, comprising wherein the at least one resistivity switching element is functionally a part of the at least one pre-charge path.

12. The circuit according to claim 7, comprising wherein the at least one resistivity switching element is functionally separated from the pre-charge path and the pull-down path.

13. The circuit according to claim 1 comprising wherein the pull-down path comprises a footer transistor of one of a n-type and a p-type.

14. The circuit according to claim 1 comprising wherein the switchable resistor is part of at least one of an OR logic element and a NOR logic element.

15. The circuit according to claim 1, comprising more than one pull-down path.

16. The circuit according to claim 15, comprising wherein one of the pull-down paths is adapted to configure the circuit and another one of the pull-down paths is adapted to operate the circuit.

17. The circuit according to claim 1, configured as being part of a dynamic Programmable Logic Array.

18. The circuit according to claim 1, comprising wherein a first resistivity value is smaller than 100 kΩ, and a second resistivity value is larger that 1 MΩ.

19. The circuit according to claim 18, comprising wherein the first resistivity value is between 1 kΩ and 100 kΩ, and a second resistivity value is between 5 MΩ and 50 MΩ.

20. A logic circuit comprising:
at least one switchable resistor having a switchable resistivity value.

21. The logic circuit according to claim 20, comprising wherein the switchable resistor is adapted to program a logic configuration of the logic circuit.

22. The logic circuit according to claim 20, comprising wherein by the switching, the resistivity value is switchable between an effectively conductive state and an effectively non-conductive state.

23. The logic circuit according to claim 20, comprising wherein the resistivity value is switchable by sending a respective current through the resistor such that the resistor is set to a first resistivity by sending a first current pulls through the resistor; and
the resistor is set to a second resistivity by sending a second current pulse through the resistor that is different from the first current.

24. The logic circuit according to claim 23, comprising wherein the resistor is a phase change resistor.

25. The logic circuit according to claim 20, comprising wherein the circuit comprises at least one resistivity switching element that is adapted to switch the at least one switchable resistor.

26. The logic circuit according to claim 25, comprising wherein the at least one resistivity switching element comprises two transistors that are arranged in parallel.

27. The logic circuit according to claim 26, comprising wherein the transistors are differently sized.

28. A method for configuring a circuit comprising:
at least one switchable resistor with a switchable resistivity, the method selectively comprising the steps of:
sending a first current through the resistor to set the resistor to a first resistivity value; and
sending a second current different from the first current through the resistor to set the resistor to a second resistivity value.

29. The method according to claim 16 comprising:
wherein the resistor is a phase change resistor; and
wherein sending the first current comprises sending a set current through the resistor to set a phase change material of the resistor to a polycrystalline state of a lower resistivity; and
wherein sending the second current comprises sending a reset current through the resistor to set a phase change material of the resistor to an amorphous state of a higher resistivity.

30. The method according to claim 28, comprising wherein the first resistivity value is smaller than 100 kΩ, and the second resistivity value is larger that 1 MΩ.

31. The method according to claim 28, comprising wherein the first resistivity value is between 1 kΩ and 100 kΩ, and the second resistivity value is between 5 MΩand 50 MΩ.

32. The method according to claim 28, comprising wherein the resistivity value is switched between an effectively conductive state and an effectively non-conductive state.

33. The method according to claim 32, comprising wherein by switching the resistivity value to the effectively conductive state, an associated pull-down path is logically connected to the circuit; and
by switching the resistivity value to the effectively non-conductive state, an associated pull-down path is logically disconnected from the circuit.

34. The method according to claim 28, comprising wherein the sending of a current through the at least one switchable resistor to switch its resistivity is controlled by at least one resistivity switching element.

35. A circuit comprising:
means for providing at least one pull-down path, wherein an amount of a current flowing through the pull-down path means is determined by a switchable resistivity value of a switchable resistor that is comprised by the circuit.
